(19) United States
(12) Patent Application Publication
(10) Pub. No.: US 2019/0053392 A1
(43) Pub. Date: Feb. 14, 2019

(54) HARD DISK STORAGE DEVICE

(71) Applicant: SHENZHEN ORICO TECHNOLOGIES CO., LTD, Shenzhen (CN)

(72) Inventor: Yeyou XU, Shenzhen (CN)

(21) Appl. No.: 16/137,577

(22) Filed: Sep. 21, 2018

Related U.S. Application Data
(63) Continuation of application No. PCT/CN2016/108911, filed on Dec. 7, 2016.

(30) Foreign Application Priority Data
Mar. 28, 2016 (CN) 201620246414.7

(51) Int. Cl. H05K 5/02; G11B 33/04

(52) U.S. Cl. CPC H05K 5/0278; G11B 33/0411

(57) ABSTRACT

A hard disk storage device includes a hard disk box configured to accommodate a hard disk body, and a hub arranged in the hard disk box. The hard disk body is electrically connected to the hub. The hub is provided with two or more USB interfaces. The USB interfaces are arranged on a side wall of the hard disk box. The hard disk storage device integrates a storage function of the hard disk and a data interface extension function of the hub, and is convenient to use and carry.

### CROSS-REFERENCE TO RELATED APPLICATIONS

This application is a continuation of International Application No. PCT/CN2016/108911 filed on Dec. 7, 2016 which claims the benefit of priority from Chinese Application No. 201620246414.7, filed on Mar. 28, 2016. The content of the aforementioned applications, including any intervening amendments thereto, are incorporated herein by reference.

### TECHNICAL FIELD

The present invention relates to a hard disk storage device.

### BACKGROUND OF THE PRESENT INVENTION

With the development of the technology of electronic products in the market, host devices (such as laptops or ultrabooks) are getting thinner and lighter, while the installation space of data transmission interfaces of the host devices is correspondingly getting smaller and smaller. The quantity of the data transmission interfaces on the host devices is also limited. Mobile storage devices are often used in our daily work, while the mobile storage devices in the current market usually only have a single storage function. When the storage devices occupy the data transmission interfaces of the host devices, it is difficult for the host devices to provide other enough data transmission interfaces for access of other electronic devices, which brings inconvenience to daily work.

### SUMMARY OF THE PRESENT INVENTION

The main object of the present invention is to provide a hard disk storage device, so as to integrate the function of hard disk storage and a data interface extension.

To achieve the above object, the present invention proposes a hard disk storage device which includes a hard disk box configured to accommodate a hard disk body, and a hub arranged in the hard disk box. The hard disk body is electrically connected to the hub. The hub is provided with two or more USB interfaces. The USB interfaces are arranged on a side wall of the hard disk box.

Preferably, the hard disk body is a 2.5-inch hard disk or 3.5-inch hard disk.

Preferably, one or more hard disk bodies are arranged.

Preferably, the USB interfaces are USB2.0 or USB3.0.

Preferably, the hard disk box includes a main body. The main body has a box body. The box body is provided with a containing cavity. The hub is arranged in the containing cavity. A plurality of USB interfaces are arranged on two adjacent side walls of the box body.

Preferably, the hub is also provided with an external power interface, and the external power interface is arranged on a side wall of the box body.

Preferably, the main body also includes a fixed frame connected with one side of the box body. The hard disk body is arranged in the fixed frame. The hard disk box also includes a lower cover, and the lower cover is buckled with the same side of the fixed frame and the box body to close the hub in the containing cavity.

Preferably, the hard disk box also includes an upper cover, and the upper cover is buckled with the other side of the fixed frame to limit the hard disk body to the fixed frame.

Preferably, the upper cover and the main body are connected through a buckle, and the lower cover and the main body are connected through the buckle.

In the technical solution of the present invention, the hard disk body and the hub are integrated into the hard disk box, the hard disk body and the hub are electrically connected; and two or more USB interfaces are arranged on the side wall of the hard disk box. Thus, the hard disk storage device of the present invention has the hard disk storage function and can also extend the data interfaces, thereby bringing convenience for human work and life.

### BRIEF DESCRIPTION OF THE DRAWINGS

To more clearly describe the technical solutions in the embodiments of the present invention or in the prior art, the drawings required to be used in the description of the embodiments or the prior art will be simply presented below. Apparently, the drawings in the following description are merely some embodiments of the present invention, and for those ordinary skilled in the art, other drawings can also be obtained according to the structures shown in drawings without contributing creative labor.

FIG. 1 is a structural schematic diagram of an embodiment of a hard disk storage device of the present invention;

FIG. 2 is an exploded structural schematic diagram of a hard disk storage device of FIG. 1 from one visual angle;

FIG. 3 is an exploded structural schematic diagram of a hard disk storage device of FIG. 1 from another visual angle; and

FIG. 4 is an exploded structural schematic diagram of a hard disk storage device of FIG. 1 from the other visual angle.

Realization of the object, functional characteristics and advantages of the present invention will be further described in combination with embodiments with reference to drawings.

### DETAILED DESCRIPTION OF THE PRESENT INVENTION

The technical solutions in the embodiments of the present invention will be clearly and fully described below in combination with the drawings in the embodiments of the present invention. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

It should be indicated that, in the embodiments of the present invention, all directional indications (such as upper, lower, left, right, front and back) are only used to explain the relative position relations, motion conditions etc. of each component under a certain attitude (as shown in the figure). If the certain attitude is changed, the directional indications are changed accordingly.

In the present invention, unless otherwise specifically regulated and defined, terms such as “connection”, “fixation” and the like shall be understood in a broad sense. For example, “fixation” may refer to fixed connection or detachable connection or integral connection, may refer to mechanical connection or electrical connection, and may refer to direct connection or indirect connection through an intermediate medium or inner communication of two elements or interaction relationship of two elements, unless otherwise specifically defined. For those ordinarily skilled in the art, the specific meanings of the above terms in the present invention may be understood according to concrete conditions.

In addition, the technical solutions in the embodiments can be combined with each other, but must be based on the realization of those ordinary skilled in the art. When the combinations of the technical solutions are contradictory or unrealizable, it shall be deemed that the combinations of the technical solutions do not exist and are not within the protection scope required by the present invention.

The present invention proposes a hard disk storage device.

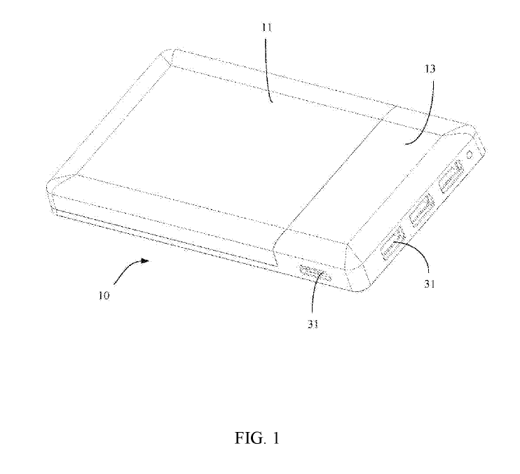

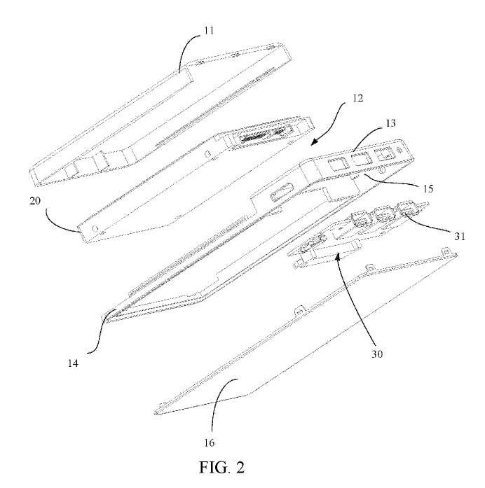

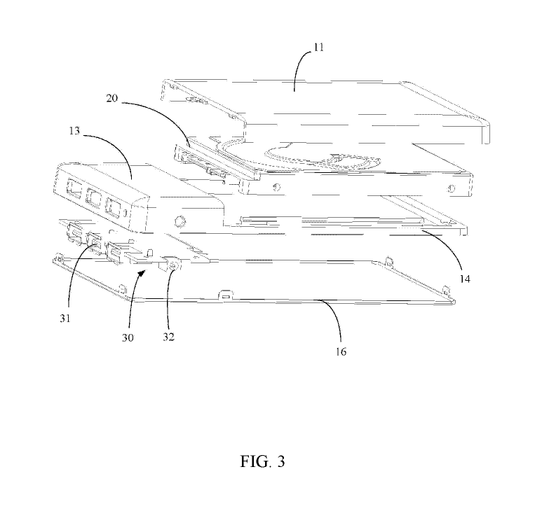

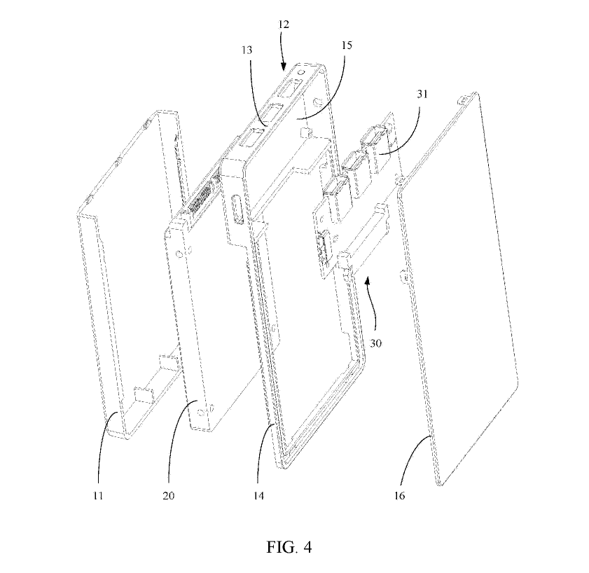

Referring to FIG. 1 to FIG. 4, FIG. 1 is a structural schematic diagram of an embodiment of a hard disk storage device of the present invention. FIG. 2 is an exploded structural schematic diagram of a hard disk storage device of FIG. 1 from a visual angle. FIG. 3 is an exploded structural schematic diagram of a hard disk storage device of FIG. 1 from another visual angle. FIG. 4 is an exploded structural schematic diagram of a hard disk storage device of FIG. 1 from still another visual angle.

In an embodiment of a hard disk storage device of the present invention, the hard disk storage device includes a hard disk box 10 configured to accommodate a hard disk body 20, and a hub 30 arranged in the hard disk box 10. The hard disk body 20 is electrically connected to the hub 30. The hub 30 is provided with two or more USB interfaces 31. The USB interfaces 31 are arranged on a side wall of the hard disk box 10.

Understandably, the hub 30 includes a main control PCB (not shown). A plurality of USB interfaces 31 are connected to the main control PCB. The hub 30 and the hard disk body 20 can be electrically connected through a SATA data line. In the present embodiment, four USB interfaces 31 are arranged. One USB interface 31 can be used for connecting a computer. Other USB interfaces 31 are used by users. The USB interfaces 31 may be USB2.0 or USB3.0. After the hard disk storage device of the present invention is connected to the computer, the hub 30 as an intermediate realizes communication between the hard disk body 20 and the computer and the computer reads and writes the hard disk body 20 through the hub 30. The hard disk box 10 may be plastic and can be produced through injection molding.

In the technical solution of the present invention, the hard disk body 20 and the hub 30 are integrated and arranged in the hard disk box 10; the hard disk body 20 and the hub 30 are electrically connected; and a plurality of USB interfaces 31 are arranged on the side wall of the hard disk box 10. Thus, the hard disk storage device of the present invention has the hard disk storage function and also has the data interface extension function of the hub 30, thereby bringing convenience for human work and life.

The hard disk body 20 may be a 2.5-inch hard disk or 3.5-inch hard disk. The 2.5-inch hard disk or 3.5-inch hard disk is used more frequently in daily life. The size of the hard disk box 10 in the present embodiment is matched with the size of the hard disk body 20. The internal space of the hard disk box 10 is enough to contain the hard disk body 20.

One or more hard disk bodies 20 are arranged. The hard disk bodies 20 can be stacked in the hard disk box 10. When the hard disk storage device in the present embodiment is provided with a plurality of hard disk bodies 20, the hard disk storage device also has a disk array function.

Referring to FIG. 2 and FIG. 4, specifically, the hard disk box 10 includes a main body 12. The main body 12 has a box body 13. The box body 13 is provided with a containing cavity 15. The hub 30 is arranged in the containing cavity 15. A plurality of USB interfaces 31 are arranged on two adjacent side walls of the box body 13.

Four USB interfaces 31 in the present embodiment are arranged on two adjacent side walls of the box body 13. One side wall is provided with one USB interface; and the other side wall is provided with three USB interfaces. In the process of using the hard disk storage device, the USB interface 31 is connected through a USB cable. The USB interface 31 on one side wall of the box body 13 faces the computer and while the USB interfaces 31 on the other side wall of the box body 13 faces the user so that the user can easily connect other electronic devices to the hard disk storage device. It is convenient to use the device.

Referring to FIG. 3, the hub 30 is also provided with an external power interface 32; and the external power interface 32 is arranged on a side wall of the box body 13. The hard disk storage device in the present embodiment can be powered through the USB interfaces 31. When the output power of the data interfaces of the computer is not enough, external commercial power can also be connected through the external power interface 32 for supplying the power, so as to ensure that the hard disk storage device is normally used in many cases.

Further, referring to FIG. 2 to FIG. 4, the main body 12 also includes a fixed frame 14 connected with one side of the box body 13; the hard disk body 20 is arranged in the fixed frame 14; the hard disk box 10 also includes an upper cover 11 and a lower cover 16; the lower cover 16 is buckled with the fixed frame 14 and the box body 13 to close the hub 30 in the containing cavity 15; and the upper cover 11 is buckled with the other side of the fixed frame 14 to limit the hard disk body 20 to the fixed frame 14.

The upper cover 11 and the main body 12 of the hard disk storage device in the present embodiment are connected through a buckle structure; and the lower cover 16 and the main body 12 are also connected through the buckle structure. The upper cover 11 and the lower cover 16 are easy to disassemble from the main body 12. In the process of using, the user can easily replace the hard disk body 20, thereby performing data read-write operation for different hard disks. And the process of using is convenient to use the device.

The above only describes preferred embodiments of the present invention and is not intended to limit the patent scope of the present invention. Any equivalent structural transformation made by using contents of the description and drawings of the present invention, or directly or indirectly used in other relevant technical fields under the inventive concept of the present invention shall be included within the protection scope of patent of the present invention.

What is claimed is:

1. A hard disk storage device, comprising a hard disk box for accommodating a hard disk body, and a hub arranged in the hard disk box, wherein the hard disk body is electrically connected to the hub; the hub is provided with two or more USB interfaces; and the USB interfaces are arranged on a side wall of the hard disk box.

2. The hard disk storage device according to claim 1, wherein the hard disk body is a 2.5-inch hard disk or 3.5-inch hard disk.

3. The hard disk storage device according to claim 2, wherein one or more hard disk bodies are arranged.

4. The hard disk storage device according to claim 1, wherein the USB interfaces are USB2.0 or USB3.0.

5. The hard disk storage device according to claim 1, wherein the hard disk box comprises a main body; the main body has a box body; the box body is provided with a containing cavity; the hub is arranged in the containing cavity; and a plurality of USB interfaces are arranged on two adjacent side walls of the box body.

6. The hard disk storage device according to claim 5, wherein the hub is also provided with an external power interface; and the external power interface is arranged on a side wall of the box body.

7. The hard disk storage device according to claim 5, wherein the main body also comprises a fixed frame connected with one side of the box body; the hard disk body is arranged in the fixed frame; the hard disk box also comprises a lower cover; and the lower cover is buckled with the same side of the fixed frame and the box body to close the hub in the containing cavity.

8. The hard disk storage device according to claim 7, wherein the hard disk box also comprises an upper cover; and the upper cover is buckled with the other side of the fixed frame to limit the hard disk body to the fixed frame.

9. The hard disk storage device according to claim 8, wherein the upper cover and the main body are connected through a buckle; and the lower cover and the main body are connected through the buckle.
